(19) United States
(12) Patent Application Publication
(10) Pub. No.: US 2025/0201506 A1
(43) Pub. Date: Jun. 19, 2025

(54) FIELD EMITTER APPARATUSES AND X-RAY SYSTEMS

(71) Applicant: Varex Imaging Corporation, Salt Lake City, UT (US)

(72) Inventor: Dave Kirkham, South Jordan, UT (US)

(73) Assignee: Varex Imaging Corporation, Salt Lake City, UT (US)

(21) Appl. No.: 18/544,290

(22) Filed: Dec. 18, 2023

(51) Int. Cl. H01J 35/06; H01J 35/14

(52) U.S. Cl. CPC H01J 35/065; H01J 35/14; H01J 2235/02

(57) ABSTRACT

Some embodiments include an apparatus, comprising: a support substrate; a field emitter device disposed on the support substrate, including a gate and a contact electrically connected to the gate; a conductive plate, including: a protrusion electrically connected to the contact of the field emitter device; and a clamp coupled to the support substrate and the conductive plate such that the conductive plate electrically connects to the contact of the field emitter device.

X-ray sources may include a field emitter. The field emitter may be secured within a vacuum enclosure. To secure the field emitter and make electrical contacts, a relatively complex structure with springs, ceramic isolators, fasteners, or the like may be required.

### BRIEF DESCRIPTION OF SEVERAL VIEWS OF THE DRAWINGS

FIG. 1 is a side view of a field emitter apparatus according to some embodiments.

FIG. 2 is a top view of a field emitter apparatus according to some embodiments.

FIG. 3A is a top view of a field emitter device according to some embodiments.

FIG. 3B is an enlargement of a field emitter of a field emitter device according to some embodiments.

FIG. 4 is a top view of a conductive plate according to some embodiments.

FIG. 5 is a top view of a support substrate according to some embodiments.

FIG. 6A is a front view of a clamp according to some embodiments.

FIG. 6B is an isometric view of a clamp according to some embodiments.

FIG. 7 is a top view of a conductive plate according to some embodiments.

FIG. 8 is a top view of a support substrate according to some embodiments.

FIG. 9 is a top view of a field emitter device according to some other embodiments.

FIG. 10 is a top view of a conductive plate according to some other embodiments.

FIG. 11 is a top view of a field emitter device according to some other embodiments.

FIG. 12 is a top view of an apparatus including a focus aperture cup according to some embodiments.

FIG. 13 is a cross-sectional view of an apparatus including a focus aperture cup according to some embodiments.

FIG. 14 is a cross-sectional view of an apparatus according to some other embodiments.

FIG. 15A is an enlargement of a portion of the apparatus of FIG. 14 according to some embodiments.

FIG. 15B is a top view of a portion of the apparatus of FIG. 14 according to some embodiments.

FIG. 16 is an enlargement of a portion of the apparatus of FIG. 14 according to some other embodiments.

FIG. 17 is a top view of an apparatus with multiple field emitters according to some other embodiments.

FIG. 18 is a top view of an apparatus with multiple field emitters according to some other embodiments.

FIG. 19 is a flowchart of a technique of forming an apparatus according to some embodiments.

FIGS. 20-23 are block diagrams showing the formation of an apparatus according to some embodiments.

FIG. 24 is a block diagram of an x-ray imaging system according to some embodiments.

### DETAILED DESCRIPTION

Embodiments include field emitter apparatuses and x-ray systems including the field emitter apparatuses. Field emitter apparatuses may be suspended within a vacuum enclosure. Electrical connections must be made to the field emitter to allow the field emitter to emit electrons. Complex structure may be used with springs, ceramic isolators, or the like to suspend the field emitter. The structure may include a relatively high number of parts. Such complex structures increase both costs and opportunities for mistakes. Embodiments described herein include less complex structures with fewer components that still support the field emitter and allow electrical connection to the field emitter.

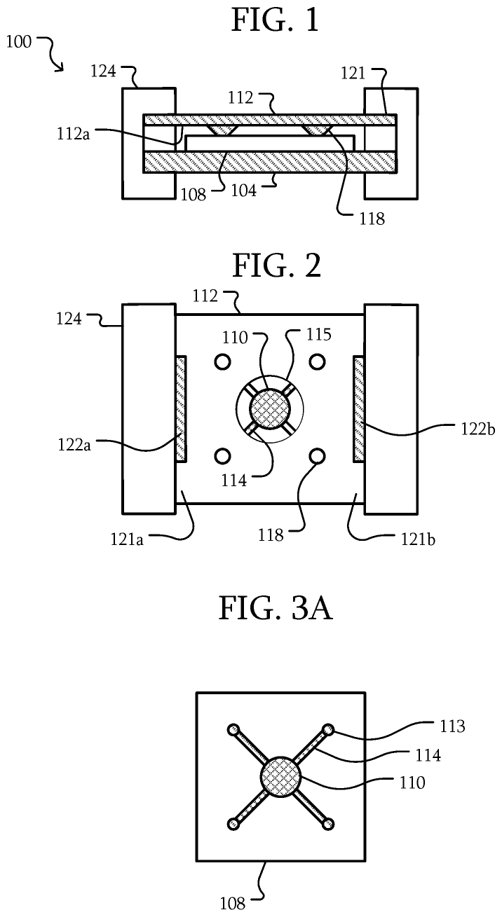

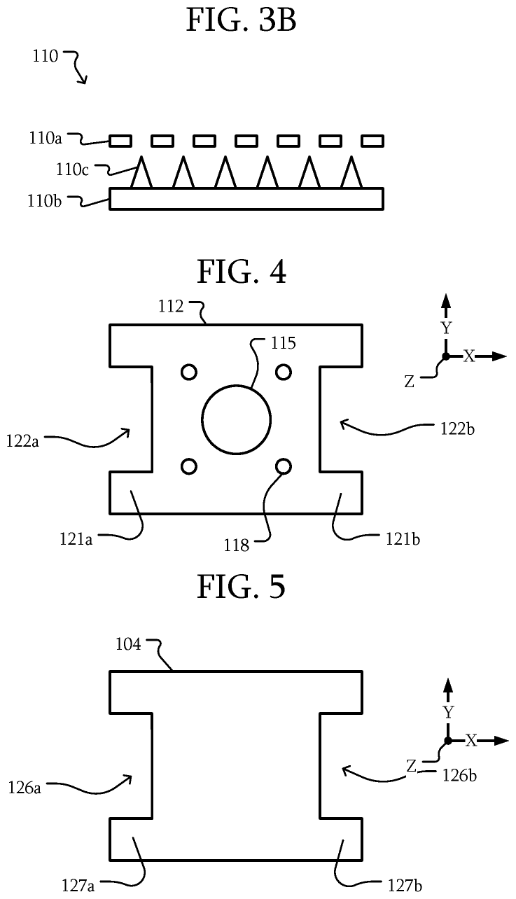

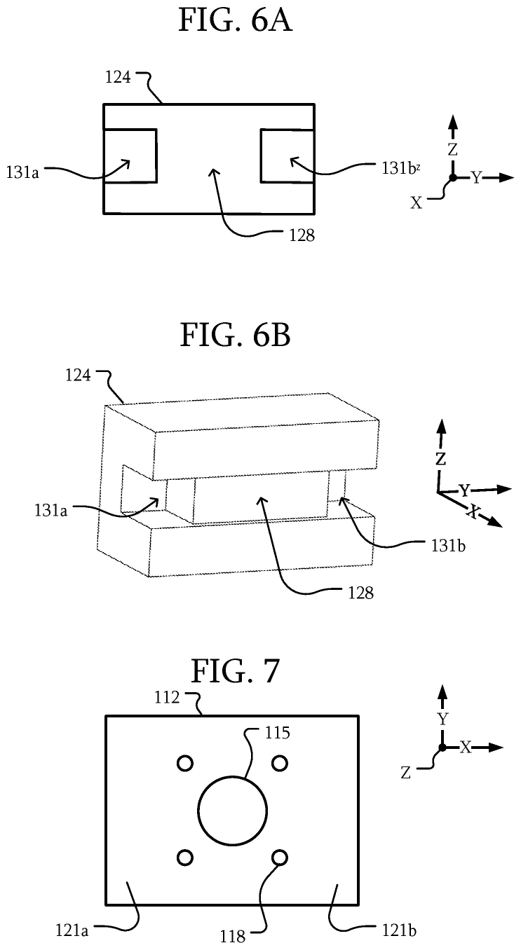

FIG. 1 is a side view of a field emitter apparatus according to some embodiments. FIG. 2 is a top view of a field emitter apparatus according to some embodiments. FIG. 3A is a top view of a field emitter device according to some embodiments. FIG. 3B is an enlargement of a field emitter of a field emitter device substrate according to some embodiments. FIG. 4 is a top view of a conductive plate according to some embodiments. FIG. 5 is a top view of a support substrate according to some embodiments. FIG. 6A is a front view of a clamp according to some embodiments. FIG. 6B is a isometric view of a clamp according to some embodiments.

Referring to FIGS. 1-6B, in some embodiments, an apparatus 100 includes a support substrate 104, a field emitter device 108, a conductive plate 112, and multiple clamps 124. The support substrate 104 may include at least a portion that is conductive. The support substrate 104 may be configured to support the field emitter device 108. The support substrate 104 may include a relatively rigid material or a material having a thickness or structure to be sufficiently rigid to support the field emitter device 108. For example, the support substrate 104 may include a metal plate having a thickness of about 0.1 inches (in.) to about 0.25 in. In other embodiments, the support substrate 104 may include a non-conductive base with a conductive layer contacting the field emitter device 108. As a result, the support substrate 104 may be electrically connected to the field emitter device 108.

The field emitter device 108 is a substrate including a field emitter 110. The field emitter may include a Spindt emitter, a carbon nanotube emitter, or the like. For example, the field emitter 110 may include a gate 110a configured to allow an electric field to be applied to the field emitter 110 so that electrons may be emitted from the field emitter 110. The field emitter device 108 may include one or more contacts 113. The contacts 113 may be electrically connected to the gate 110a through conductive traces 114. This example includes four contacts 113 and corresponding traces 114; however, in other embodiments, the number of contacts 113 and traces 114 may be different. Although traces 114 are used as an example of how the contacts 113 may be electrically connected to the field emitter 110, in other embodiments, the electrical connection may be formed through additional and/or different structures, such as a layer of the field emitter device 108, vias, bonded wire connections, or the like. The field emitter 110 may include a conductive substrate 110b including emitters 110c. The application of an electric field between the gate 110a and the conductive substrate 110b may cause electrons to be emitted from the emitters 110c. Although the field emitter 110 has been illustrated with a particular size and shape, in other embodiments, the size and shape may be different. In addition, multiple field emitters 110 may be part of the same field emitter device 108, each being electrically connected to the same or different contacts 113.

The conductive plate 112 includes a conductive structure that is at least conductive on a surface 112a facing the field emitter device 108. The conductive plate 112 may include a metal plate, a plastic plate with a conductive surface 112a, or the like.

The conductive plate 112 includes protrusions 118. The protrusions 118 extend from the conductive plate 112 towards the field emitter device 108. The protrusions 118 may have a conical shape; however, in other embodiments, the shape may be different. The protrusions 118 are electrically connected to the contacts 113 of the field emitter device 108. The conductive plate 112 includes an opening 115. The opening 115 may expose the field emitter 110 of the field emitter device 108.

The conductive plate 112 includes multiple compliant tabs 121. The compliant tabs 121 are disposed on a perimeter of the conductive plate 112. The compliant tabs 121 have a structure and material that allows the compliant tabs 121 to be deformed towards the support substrate 104.

The clamps 124 may be structures that are rigid or less compliant than the compliant tabs 121. For example, the clamps 124 may include ceramic or other insulating materials. The clamps 124 are coupled to the support substrate 104 and the conductive plate 112 such that the compliant tabs 121 are deformed towards the support substrate 104. As a result, a force is applied by the clamps 124 to the support substrate 104 and the conductive plate 112 to compress the support substrate 104 and the conductive plate 112 together. The field emitter device 108 is disposed between the support substrate 104 and the conductive plate 112. As a result, the field emitter device 108 is compressed between the support substrate 104 and the conductive plate 112. As the protrusions 118 extend towards the field emitter device 108 the protrusions 118 are forced into the field emitter device 108. In particular, one or more of the protrusions 118 is compressed on to a corresponding one of the contacts 113, making electrical contact. As a result, an electrical connection is formed between the gate 110a and the conductive plate 112.

In some embodiments, the thickness of the compliant tabs 121 and the shape may be selected such that when clamped in the clamps 124, a force within a desired range is applied by the protrusions 118 to the contacts 113. The desired range may include a force that maintains an electrical connection between the protrusions 118 and the contacts 113 over an operating range and lifetime of the apparatus 100. The number of protrusions 118, the location on the conductive plate 112, the shape of the protrusions 118, or the like may be varied to select a desired force. In some embodiments, the force applied by the protrusion 118 may be sufficient to maintain the field emitter device 108 in position on the support substrate 104.

In some embodiments, no fasteners are used when clamping the conductive plate 112 to the support substrate 104. The support substrate 104, the field emitter device 108, the conductive plate 112, and the clamps 124 may be the only components of the apparatus 100. As a result, the number of components of the apparatus 100, the complexity of the apparatus 100, and the assembly time for the assembly 100 may be reduced relative to other assemblies that may be used for field emission.

In some embodiments, the compliant tabs 121 of the conductive plate 112 are separated by notches 122. In this example, the conductive plate 112 includes two compliant tabs 121a and 121b on each of two opposite sides. The compliant tabs 121a and 121b are separated by a notch 122a and 122b, respectively.

The support substrate 104 may include multiple notches 126. In this example, the support substrate includes two notches 126a and 126b. In some embodiments, the notches 126 may have substantially the same width along the Y axis as the notches 122 of the conductive plate 112. In some embodiments, the length along the X axis may also be substantially the same. Substantially the same includes mechanical tolerances, manufacturing tolerances, or the like. In some embodiments, the size, shape, placement, number, or the like of the notches 122 may be different from the notches 126.

The clamps 124 may include a portion 128. The portion 128 may extend in the X direction. The portion 128 may result in notches 131. The notches 131 may correspond to the notches 122 and 126 of the conductive plate 112 and the support substrate 104. In this example, the clamps 124 include two notches 131a and 131b. In some embodiments, as described above, the configurations of the conductive plate 112 and the support substrate 104 may be different. Accordingly, the notches 131a may have a different configuration to accommodate the differences in the conductive plate 112 and the support substrate 104.

In some embodiments, the portions 128 provide alignment between the conductive plate 112 and the support substrate 104. The portions 128, notches 122, and notches 126 may be complementary structures. When the clamps 124 are applied to the conductive plate 112 and the support substrate 104, the portions 128 may cause the conductive plate 112 and the support substrate 104 to be disposed in a known alignment, such as an alignment where the protrusions 118 are aligned with the contacts 113 in the X-Y plane. In some embodiments, the portions 128 correspond with the notches 122 and 126 on a one-to-one basis.

Although multiple clamps 124 have been used as examples, in some embodiments, a single clamp 124 may engage with the conductive plate 112 and the support substrate 104.

FIG. 7 is a top view of a conductive plate according to some embodiments. Although the conductive plate 112 has been described as having multiple compliant tabs 121 on each side, in some embodiments, the conductive plate 112 may include only one compliant tab 121 on each side, or only one compliant tab 121 on only one side. However, the resilience of the two tabs 121 or the single tab 121 may still cause the conductive plate 112 to be pressed towards the support substrate 104 with a desired force.

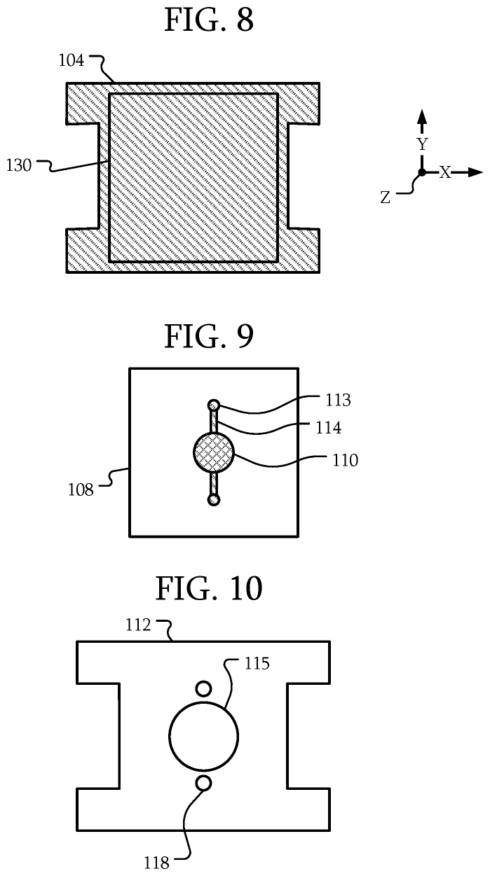

FIG. 8 is a top view of a support substrate according to some embodiments. Referring to FIGS. 3A and 8, in some embodiments, the support substrate 104 includes a depression 130. The depression 130 may be configured to receive the field emitter device 108. The depression 130 may have a shape configured to constrain the movement of the field emitter device 108 in the X and Y directions. In a particular example, the field emitter device 108 may have a rectangular projection on the X-Y plane. The depression 130 may have a corresponding rectangular shape. The dimensions of the depression 130 may be the same as the field emitter device 108 within mechanical tolerances and offsets to allow for reliable placement of the field emitter device 108 in the depression 130, but constraining the movement in the X-Y plane to align the contacts 113 to the protrusions 118. As described above, the clamps 124 may align the support substrate 104 and the conductive plate 112. As the depression 130 may align the field emitter device 108 to the support substrate 104, the field emitter device 108 may be aligned with the conductive plates 112 and the protrusions 118.

FIG. 9 is a top view of a field emitter substrate according to some other embodiments. In some embodiments, the field emitter device 108 may include a different number of contacts 113. The contacts 113 may be disposed in a different position from those of the field emitter device 108 of FIG. 3A. In this example, the field emitter device 108 includes two contacts 113.

FIG. 10 is a top view of a conductive plate according to some other embodiments. Referring to FIGS. 9 and 10, in some embodiments, the conductive plate 112 may include the same number of protrusions 118 as the number of contacts 113 on the field emitter device 108. The protrusions 118 may still be in a position to be aligned to make electrical contact with the contacts 113.

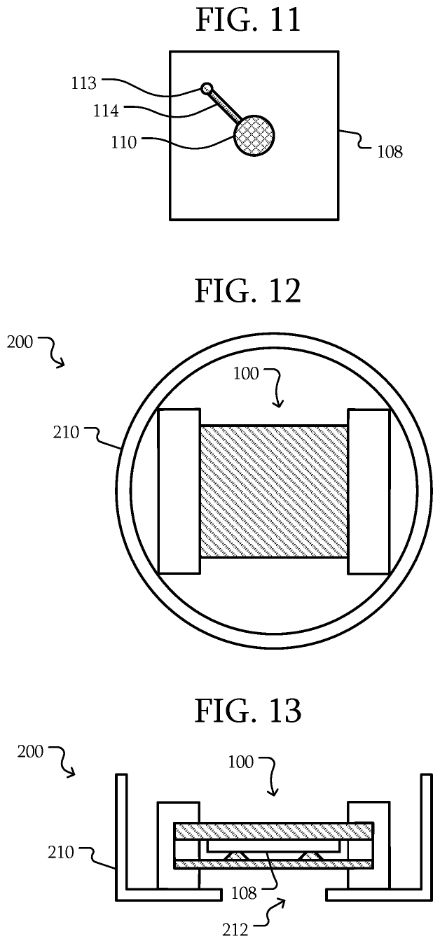

FIG. 11 is a top view of a field emitter substrate according to some other embodiments. In some embodiments, a number of the contacts 113 of the conductive plate 112 is different from a number of the contacts 113 of the field emitter device 108. Here, the field emitter device 108 includes one contact 113. An apparatus 100 may include this field emitter device 108 but still use the conductive plate 112 of FIG. 4 with four protrusions 118. One of the four protrusions 118 may still electrically connect to the contact 113. The other protrusions 118 may contact other areas of the field emitter substrate where there is no conductive structure.

FIG. 12 is a top view of an apparatus including a focus aperture cup according to some embodiments. FIG. 13 is a cross-sectional view of an apparatus including a focus aperture cup according to some embodiments. Referring to FIGS. 12 and 13, in some embodiments, an apparatus 200 may include a focus aperture cup 210 and an apparatus 100 similar to the apparatuses 100 described herein. Some of the reference numbers of the apparatus 100 may be omitted for clarity but may still be present as described with respect to FIGS. 1-11.

The focus aperture cup 210 may include conductive materials such as stainless steel or other vacuum compatible conductive materials. The focus aperture cup 210 may include an opening 212. The opening 212 may permit electrons from the field emitter device 108 to exit the apparatus 200. The apparatus 100, including the support substrate 104, the field emitter device 108, the conductive plate 112, and the clamps 124 are disposed in the focus aperture cup 210. As described below, the apparatus 100 may be secured in the focus aperture cup 210 by different techniques.

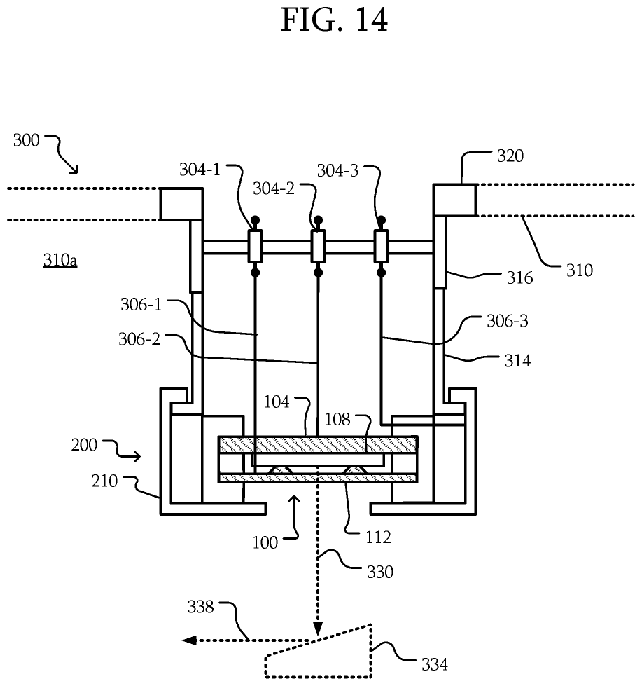

FIG. 14 is a cross-sectional view of an apparatus according to some other embodiments. In some embodiments, an apparatus 300 may include an apparatus 200 similar to those described above. The apparatus 200 may be attached to a support structure 314. The support structure 314 may include a conductive material such as stainless steel or other vacuum compatible conductive materials. The support structure 314 may have a shape corresponding to the focus aperture cup 210 such that the support structure 314 may be attached to the focus aperture cup 210 as described herein.

The apparatus 300 includes an insulator 316. The insulator 316 may include an insulating material such as ceramic or other vacuum compatible insulators. The insulator 316 is connected to the apparatus 200. In some embodiments, the support structure 314 may connect the insulator 316 to the apparatus 200. However, in other embodiments, the insulator 316 may be directly attached to the apparatus 200.

Multiple feedthroughs 304 may be supported by the insulator 316. Three feedthroughs 304 are illustrated, however in other embodiments, a different number of feedthroughs 304 may be supported by the insulator 316.

The feedthroughs 304 provide electrical connections through the insulator 316 to components of the apparatus 200. For example, the feedthrough 304-1 is electrically connected to the conductive plate 112. The feedthrough 304-2 is electrically connected to the support substrate 104. The feedthrough 304-3 is electrically connected to the focus aperture cup 210.

In some embodiments, the insulator 316 is attached to a flange 320. The flange 320 may be attached to a vacuum enclosure 310. As a result, the apparatus 200 and hence the apparatus 100 may be disposed within the interior 310a of the vacuum enclosure 310. The feedthroughs 304 may provide electrical connections to structures within the interior 310a of the vacuum enclosure 310.

A target 334 may be disposed within the interior 310a of the vacuum enclosure 310. The target 334 may be configured to emit x-rays 338 in response to electrons 330 emitted from the field emitter device 108 of the apparatus 100. The target 332 may include materials such as tungsten (W), molybdenum (Mo), rhodium (Rh), silver (Ag), rhenium (Re), palladium (Pd), or the like.

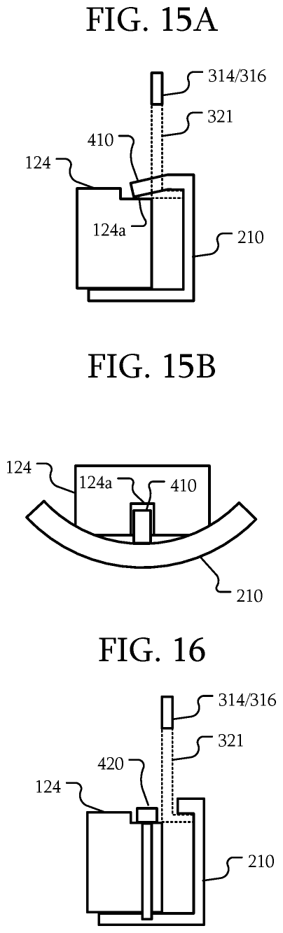

FIG. 15A is an enlargement of a portion of the apparatus of FIG. 12 according to some embodiments. FIG. 15B is a top view of a portion of the apparatus of FIG. 12 according to some embodiments. Referring to FIGS. 12, 15A, and 15B, in some embodiments, the focus aperture cup 210 includes a plurality of tabs 410. The clamps 124 may include multiple notches 124a. The tabs 410 are disposed in locations corresponding to the notches 124a of the clamps 124. The tabs 410 may be bent to be disposed in the notches 124a. As a result, the apparatus 100 may be attached to the focus aperture cup 210. An opening 321 in the support structure 314 or the insulator 316 may allow access to the notches 124a so that the tabs 410 may be bent into the notches 124a.

FIG. 16 is an enlargement of a portion of the apparatus of FIG. 14 according to some other embodiments. Referring to FIGS. 14 and 16, in some embodiments, fasteners 420 such as screws, rivets, or the like may attach the clamps 124 to the focus aperture cup 210. The opening 321 may allow access to the fasteners 420 through the support structure 314 or the insulator 316.

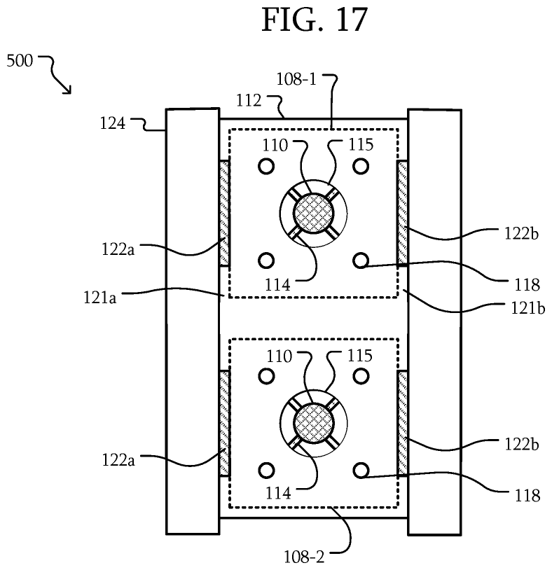

FIG. 17 is a top view of an apparatus with multiple field emitters according to some other embodiments. An apparatus 500 may be similar to the apparatus 100 described above. However, the apparatus 500 includes multiple field emitter devices 108 illustrated with dashed lines. In this example, the apparatus 500 includes two field emitter devices 108-1 and 108-2. Each includes the components of a field emitter device 108 as described above. The field emitter devices 108 may be identical or different according to the variations described above including a gate 110a and at least one contact 113 electrically connected to the gate 110a. In addition, each of the field emitter devices 108 may have the same or different emitter structures. The dimensions of each field emitter device 108 may be the same or different. The configuration of the compliant tabs 121 may be the same or different for each field emitter device 108.

In some embodiments, the conductive plate 112 includes multiple protrusions 118 with at least one associated with each of the field emitter device 108. As a result, each of the field emitter substrates 108 are electrically connected to the conductive plate 112.

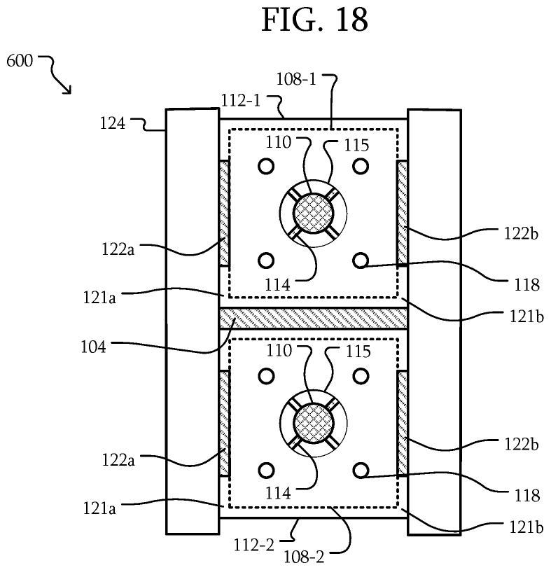

FIG. 18 is a top view of an apparatus with multiple field emitters according to some other embodiments. In some embodiments, an apparatus 600 is similar to the apparatuses 100 and 500 described above. However, the apparatus 600 includes multiple conductive plates 112. In this example, the apparatus 600 includes two conductive plates 112-1 and 112-2. Each of the conductive plates 112 may be similar to the conductive plates 112 described above, allowing connection to the corresponding one of the field emitter substrates 108. The clamps 124 may be configured to apply pressure to compliant tabs 121 of each of the conductive plates 112 to press the conductive plates 112 into the corresponding field emitter substrates 108.

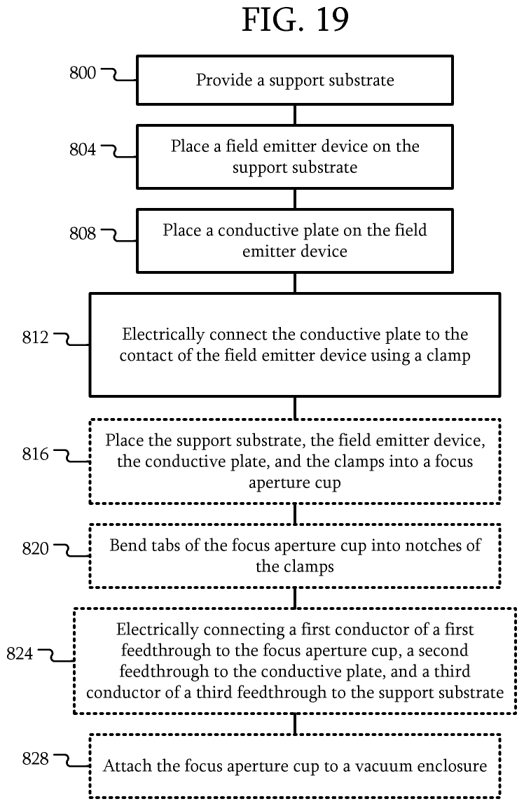

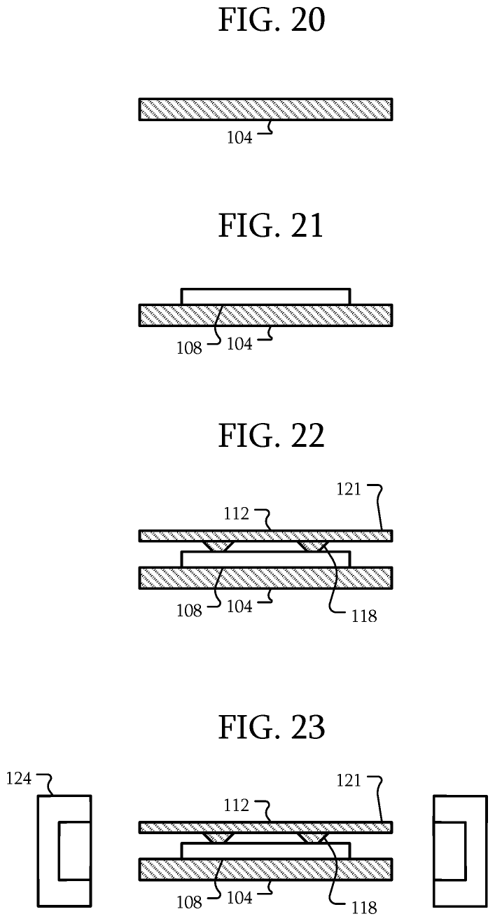

FIG. 19 is a flowchart of a technique of forming an apparatus according to some embodiments. FIGS. 20-23 are block diagrams showing the formation of an apparatus according to some embodiments. Forming the apparatus 100 of FIGS. 1-6B will be used as an example. Referring to FIGS. 19 and 20, in 800, a support substrate 104 is provided. Referring to FIGS. 19 and 21, in 804, a field emitter device 108 is placed on the support substrate 104. In some embodiments, the substrate may be merely placed on the support substrate 104 without any adhesive or other materials or fasteners to attach the field emitter device 108 to the support substrate 104. In some embodiments, the support substrate 104 includes the depression 130 of FIG. 8. The field emitter device 108 may be placed in the depression 130 as part of placing the field emitter device 108 on the support substrate 104.

Referring to FIGS. 19 and 22, in 808, a conductive plate 112 is placed on the field emitter device 108. The conductive plate 112 may be aligned with the field emitter device 108 such that protrusions 118 of the conductive plate 112 are disposed over or contact the contacts 113 of the field emitter device 108. However, in other embodiments, the conductive plate 112 may be aligned with the field emitter device 108 as part of a later operation.

Referring to FIGS. 19 and 23, in 812, the conductive plate is electrically connected to the contact of the field emitter device using a clamp 124. For example, the compliant tabs of the conductive plate 112 are compressed towards the support substrate 104 using clamps 124 such that the protrusion 118 is electrically connected to the contact 113 of the field emitter device 108. For example, as the clamps 124 may be moved towards the conductive plate 112 and support substrate 104. As the conductive plate 112 and support substrate 104 enter the notches 131, the conductive plate 112 is compressed towards the support substrate 104. The portions 128 may align the conductive plate 112 and support substrate 104.

In some embodiment, after 812, in 816, the support substrate 104, the field emitter device 108, the conductive plate 112, and the clamps 124 are placed into a focus aperture cup 210 as illustrated in FIGS. 10 and 11.

Referring to FIGS. 15A, 15B, and 19, in some embodiments, after 816, in 820, tabs 410 of the focus aperture cup 210 are bent into notches of the clamps 124. As a result, the apparatus 100 may be retained within the focus aperture cup 210.

Referring to FIGS. 14 and 19, in some embodiments, in 824 a first conductor of a first feedthrough 304-3 is electrically connected to the focus aperture cup 210, a second conductor of a second feedthrough 304-2 to the conductive plate 112, and a third conductor of a third feedthrough 304-1 is electrically connected to the support substrate 104. The electrical connections may be formed by wires that are soldered brazed, or otherwise electrically connected to the feedthrough 304 and the corresponding structure.

In 828, the focus aperture cup 210 may be attached to a vacuum enclosure 310. For example, a flange 320 attached to the insulator 316 supporting the feedthroughs 304 may be brazed, welded, otherwise attached in a vacuum compatible manner to the vacuum enclosure 310.

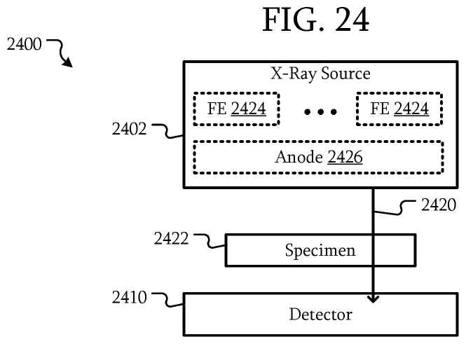

FIG. 24 is a block diagram of an x-ray imaging system according to some embodiments. The x-ray imaging system 2400 includes an x-ray source 2402 and detector 2410. The x-ray source 2402 may include an apparatus 100, 200, 300, 500, 600, or the like as described above. In some embodiments, the x-ray source 2402 includes multiple field emitters (FE) 2424. Electron beams from the field emitters 2424 may be directed towards an anode 2426 to generate x-rays 2420. The x-ray source 2402 is disposed relative to the detector 2410 such that x-rays 2420 may be generated to pass through a specimen 2422 and detected by the detector 2410. In some embodiments, the detector 2410 is part of a medical imaging system. In other embodiments, the x-ray imaging system 2400 may include a portable vehicle scanning system as part of a cargo scanning system. The system 2400 may be any system that may include an x-ray detector.

Some embodiments include an apparatus 100, comprising: a support substrate 104; a field emitter device 108 disposed on the support substrate 104, including a gate 110a and a contact 113 electrically connected to the gate 110a; a conductive plate 112, including: a protrusion 118 electrically connected to the contact 113 of the field emitter device 108; and a clamp 124 coupled to the support substrate 104 and the conductive plate 112 such that the conductive plate 112 electrically connects to the contact 113 of the field emitter device 108.

In some embodiments, the support substrate 104 includes a depression 130; and the field emitter device 108 is disposed in the depression 130.

In some embodiments, the clamp 124 is one of a plurality of clamps 124 coupled to the support substrate 104 and the conductive plate 112; the conductive plate 112 further comprises a plurality of compliant tab s 121 disposed on a perimeter of the conductive plate 112; the compliant tab s 121 of the conductive plate 112 are separated by a plurality of notches 122; the support substrate 104 includes a plurality of notches 122; and each of the clamps 124 includes a portion extending within a corresponding one of the notches 122 of the conductive plate 112 and a corresponding one of the notches 122 of the support substrate 104.

In some embodiments, a number of protrusions 118 of the conductive plate 112 is different from a number of contacts 113 of the field emitter device 108.

In some embodiments, the apparatus 100 further comprises a focus aperture cup 210; wherein: the support substrate 104, the field emitter device 108, the conductive plate 112, and the clamp 124 are disposed in the focus aperture cup 210.

In some embodiments, the apparatus 100 further comprises a plurality of fasteners coupling the clamp 124 to the focus aperture cup 210.

In some embodiments, the focus aperture cup 210 includes a plurality of tabs; the clamp 124 includes a plurality of notches 122; and each of the tabs is disposed in a corresponding one of the notches 122.

In some embodiments, the apparatus 100 further comprises an insulator 316 connected to the focus aperture cup 210.

In some embodiments, the apparatus 100 further comprises a first feedthrough 204 supported by the insulator 316 including a first conductor electrically connected to the focus aperture cup 210; a second feedthrough 204 supported by the insulator 316 including a second conductor electrically connected to the conductive plate 112; and a third feedthrough 204 supported by the insulator 316 including a third conductor electrically connected to the support substrate 104.

In some embodiments, the apparatus 100 further comprises a vacuum enclosure 310; and a target 334 configured to emit x-rays disposed within the vacuum enclosure 310; wherein: the field emitter device 108 is disposed within the vacuum enclosure 310 such that electrons emitted from the field emitter device 108 are incident on the target 334.

In some embodiments, the field emitter device 108 is one of a plurality of field emitter devices 108, each including a gate 110a and a contact 113 electrically connected to the gate 110a.

In some embodiments, the protrusion 118 is one of a plurality of protrusions 118 of the conductive plate 112; and for each of the field emitter devices 108, the contact 113 is electrically connected to a corresponding one of the protrusions 118 of the conductive plate 112.

In some embodiments, the conductive plate 112 is one of a plurality of conductive plates 112, each conductive plate 112 including: a protrusion 118 electrically connected to the contact 113 of a corresponding one of the field emitter devices 108; and a plurality of compliant tab s 121 disposed on a perimeter of the conductive plate 112.

Some embodiments include a method, comprising: providing a support substrate 104; placing a field emitter device 108 on the support substrate 104, the field emitter device 108 including a gate 110a and a contact 113 electrically connected to the gate 110a; placing a conductive plate 112 on the field emitter device 108, the conductive plate 112, including: a protrusion 118 configured to electrically connect to the contact 113 of the field emitter device 108; and electrically connecting the conductive plate 112 to the contact 113 of the field emitter device 108 using a clamp 124 The method of claim 14, further comprising: placing the support substrate 104, the field emitter device 108, the conductive plate 112, and the clamps 124 into a focus aperture cup 210.

In some embodiments, the method further comprises bending tabs of the focus aperture cup 210 into notches 122 of the clamps 124.

In some embodiments, the method further comprises electrically connecting a first conductor of a first feedthrough 204 to the focus aperture cup 210; electrically connecting a second conductor of a second feedthrough 204 to the conductive plate 112; and electrically connecting a third conductor of a third feedthrough 204 to the support substrate 104.

In some embodiments, the method further comprises attaching the focus aperture cup 210 to a vacuum enclosure 310.

Some embodiments include an apparatus 100, comprising: a support substrate 104; a field emitter device 108 including a field emitter and disposed on the support substrate 104; a conductive plate 112; and a clamp 124 coupling the support substrate 104 to the conductive plate 112; wherein when the clamp 124 couples the support substrate 104 to the conductive plate 112, the field emitter is electrically connected to the conductive plate 112.

In some embodiments, the conductive plate 112 deforms when the clamp 124 couples the support substrate 104 to the conductive plate 112.

Although the structures, devices, methods, and systems have been described in accordance with particular embodiments, one of ordinary skill in the art will readily recognize that many variations to the particular embodiments are possible, and any variations should therefore be considered to be within the spirit and scope disclosed herein. Accordingly, many modifications may be made by one of ordinary skill in the art without departing from the spirit and scope of the appended claims.

The claims following this written disclosure are hereby expressly incorporated into the present written disclosure, with each claim standing on its own as a separate embodiment. This disclosure includes all permutations of the independent claims with their dependent claims. Moreover, additional embodiments capable of derivation from the independent and dependent claims that follow are also expressly incorporated into the present written description. These additional embodiments are determined by replacing the dependency of a given dependent claim with the phrase “any of the claims beginning with claim [x] and ending with the claim that immediately precedes this one,” where the bracketed term “[x]” is replaced with the number of the most recently recited independent claim. For example, for the first claim set that begins with independent claim 1, claim 4 can depend from either of claims 1 and 3, with these separate dependencies yielding two distinct embodiments; claim 5 can depend from any one of claim 1, 3, or 4, with these separate dependencies yielding three distinct embodiments; claim 6 can depend from any one of claim 1, 3, 4, or 5, with these separate dependencies yielding four distinct embodiments; and so on.

Recitation in the claims of the term “first” with respect to a feature or element does not necessarily imply the existence of a second or additional such feature or element. Elements specifically recited in means-plus-function format, if any, are intended to be construed to cover the corresponding structure, material, or acts described herein and equivalents thereof in accordance with 35 U.S.C. § 112(f). Embodiments of the invention in which an exclusive property or privilege is claimed are defined as follows.

1. An apparatus, comprising:
a support substrate;
a field emitter device disposed on the support substrate, including a gate and a contact electrically connected to the gate;
a conductive plate, including:
a protrusion electrically connected to the contact of the field emitter device; and
a clamp coupled to the support substrate and the conductive plate such that the conductive plate electrically connects to the contact of the field emitter device.

2. The apparatus of claim 1, wherein:
the support substrate includes a depression; and
the field emitter device is disposed in the depression.

3. The apparatus of claim 1, wherein:
the clamp is one of a plurality of clamps coupled to the support substrate and the conductive plate;
the conductive plate further comprises a plurality of compliant tabs disposed on a perimeter of the conductive plate;
the compliant tabs of the conductive plate are separated by a plurality of notches;
the support substrate includes a plurality of notches; and
each of the clamps includes a portion extending within a corresponding one of the notches of the conductive plate and a corresponding one of the notches of the support substrate.

4. The apparatus of claim 1, wherein:
a number of protrusions of the conductive plate is different from a number of contacts of the field emitter device.

5. The apparatus of claim 1, further comprising:
a focus aperture cup;
wherein:
the support substrate, the field emitter device, the conductive plate, and the clamp are disposed in the focus aperture cup.

6. The apparatus of claim 5, further comprising:
a plurality of fasteners coupling the clamp to the focus aperture cup.

7. The apparatus of claim 5, wherein:
the focus aperture cup includes a plurality of tabs;
the clamp includes a plurality of notches; and
each of the tabs is disposed in a corresponding one of the notches.

8. The apparatus of claim 5, further comprising:
an insulator connected to the focus aperture cup.

9. The apparatus of claim 8, further comprising:
a first feedthrough supported by the insulator including a first conductor electrically connected to the focus aperture cup;
a second feedthrough supported by the insulator including a second conductor electrically connected to the conductive plate; and
a third feedthrough supported by the insulator including a third conductor electrically connected to the support substrate.

10. The apparatus of claim 5, further comprising:
a vacuum enclosure; and
a target configured to emit x-rays disposed within the vacuum enclosure;
wherein:
the field emitter device is disposed within the vacuum enclosure such that electrons emitted from the field emitter device are incident on the target.

11. The apparatus of claim 1, wherein:
the field emitter device is one of a plurality of field emitter devices, each including a gate and a contact electrically connected to the gate.

12. The apparatus of claim 11, wherein:
the protrusion is one of a plurality of protrusions of the conductive plate; and
for each of the field emitter devices, the contact is electrically connected to a corresponding one of the protrusions of the conductive plate.

13. The apparatus of claim 11, wherein:
the conductive plate is one of a plurality of conductive plates, each conductive plate including:
a protrusion electrically connected to the contact of a corresponding one of the field emitter devices; and
a plurality of compliant tabs disposed on a perimeter of the conductive plate.

14. A method, comprising:
providing a support substrate;
placing a field emitter device on the support substrate, the field emitter device including a gate and a contact electrically connected to the gate;
placing a conductive plate on the field emitter device, the conductive plate, including:
a protrusion configured to electrically connect to the contact of the field emitter device; and
electrically connecting the conductive plate to the contact of the field emitter device using a clamp

15. The method of claim 14, further comprising:
placing the support substrate, the field emitter device, the conductive plate, and the clamps into a focus aperture cup.

16. The method of claim 15, further comprising:
bending tabs of the focus aperture cup into notches of the clamps.

17. The method of claim 15, further comprising:
electrically connecting a first conductor of a first feedthrough to the focus aperture cup;
electrically connecting a second conductor of a second feedthrough to the conductive plate; and
electrically connecting a third conductor of a third feedthrough to the support substrate.

18. The method of claim 15, further comprising:
attaching the focus aperture cup to a vacuum enclosure.

19. An apparatus, comprising:
a support substrate;
a field emitter device including a field emitter and disposed on the support substrate;
a conductive plate; and
a clamp coupling the support substrate to the conductive plate;
wherein when the clamp couples the support substrate to the conductive plate, the field emitter is electrically connected to the conductive plate.

20. The apparatus of claim 19, wherein:
the conductive plate deforms when the clamp couples the support substrate to the conductive plate.
